(19) United States
(12) Patent Application Publication
(10) Pub. No.: US 2003/0058041 A1
(43) Pub. Date: Mar. 27, 2003

(54) Variable gain amplifier

(76) Inventor: Haruhiko Koizumi, Osaka (JP)

Correspondence Address: NIXON PEABODY, LLP, 8180 GREENSBORO DRIVE, SUITE 800, MCLEAN, VA, 22102, US

(21) Appl. No.: 09/973,818

(22) Filed: Oct. 11, 2001

(30) Foreign Application Priority Data
Oct. 13, 2000 (JP) 2000-313182

(51) Int. Cl. H03F 1/14

(52) U.S. Cl. 330/51

(57) ABSTRACT

The variable gain amplifier of the present invention includes: an amplifier for amplifying an input signal and outputting the amplified signal; an amplifier output-side switch connected to the output of the amplifier at one terminal, whether the amplifier output-side switch is ON or OFF being controlled with a control voltage; and a low-gain circuit including an attenuator for attenuating an input signal and outputting the attenuated signal, and a first switch connected in series with the attenuator, whether the first switch is ON or OFF being controlled with the control voltage. One terminal of the low-gain circuit is connected to an input of the amplifier while the other terminal is connected to the other terminal of the amplifier output-side switch. During low-gain operation, power supply to the amplifier is stopped, and the first switch is ON and the amplifier output-side switch is OFF according to the control voltage.

### BACKGROUND OF THE INVENTION

The present invention relates to a variable gain amplifier for amplifying a high-frequency signal used for wireless communication systems and the like.

In receiver circuits used for recent digital wireless communication systems adopting code division multiple access (CDMA) and other schemes, high linearity is required over a wide range of input signal levels. To meet this requirement, gain is controlled in a first-stage high-frequency amplifier of a receiver circuit in accordance with input signal levels, where high-gain operation is performed when input signal is weak while low-gain operation is performed when input signal is strong. To perform low-gain operation , a signal is guided to bypass an amplifier, or is attenuated in the amplifier.

Hereinafter, a conventional variable gain amplifier will be described with reference to FIG. 6. FIG. 6 is a circuit diagram of a conventional variable gain amplifier, which is disclosed in Japanese Laid-Open Patent Publication No. 4-238407. Note that in FIG. 6 and the drawings to follow, G, D, S respectively denote the gate, drain, and source of a field effect transistor (FET). In FIG. 6, the gate of a FET 81 is connected to an input terminal 84 of the variable gain amplifier via an input matching circuit 83. The drain of the FET 81 is connected to an output terminal 86 via an output matching circuit 85. The source of the FET 81 is grounded.

The source of a FET 82 is connected to the gate of the FET 81, and the drain of the FET 82 is connected to the drain of the FET 81 via a capacitor 87. The gate of the FET 82 is connected to a control terminal 89 via a capacitor 88. A voltage Vg is applied to the gate of the FET 81 via a resistor 90 and the input matching circuit 83. A voltage Vdd is applied to the drain of the FET 81 via a choke coil 91 and the output matching circuit 85.

The operation of the conventional variable gain amplifier described above will be described. The FET 81 is used as a high-frequency amplifier, while the FET 82 is used as a variable resistor, in which the drain-source resistance is controlled with a voltage applied to the gate.

In other words, this conventional variable gain amplifier serves as a negative feedback amplifier including the FET 82 operating as a variable resistor and the capacitor 87. When input signal is weak, the drain-source resistance of the FET 82 is made large by decreasing the voltage at the control terminal 89 to a value less than a threshold voltage of the FET 82 (for example, -3 V). This reduces the feedback amount and thus increases the gain of the amplifier.

On the contrary, when input signal is strong, the drain-source resistance of the FET 82 is made small by increasing the voltage at the control terminal 89 to a value more than the threshold voltage of the FET 82 (for example, 0 V). This increases the feedback amount and thus decreases the gain. In this way, by changing the control voltage, that is, the voltage applied to the gate of the FET 82, the gain of the FET 81 is controlled.

However, the conventional variable gain amplifier described above has the following problem. Although the control voltage is changed to enable low-gain operation, the drain voltage and the gate-source voltage of the FET 81 as the amplifier remain constant. As a result, a constant current invariably flows to the FET 81, and thus the FET 81 consumes constant power.

To reduce the current during the low-gain operation, the FET 81 may be controlled. That is, the gate-source voltage of the FET 81 may be made close to the threshold voltage, or the drain voltage thereof may be reduced. However, this control changes the input and output impedances of the FET 81, and thus changes the return loss. Consequently, a large difference arises in the return loss of the variable gain amplifier between the high-gain operation and the low-gain operation.

### SUMMARY OF THE INVENTION

An object of the present invention is providing a variable gain amplifier capable of switching the gain with change in control voltage, in which the current consumption can be reduced to near zero during low-gain operation and the output return loss does not deteriorate during both high-gain operation and low-gain operation.

The variable gain amplifier of the present invention includes: an amplifier for amplifying an input signal and outputting the amplified signal; an amplifier output-side switch connected to an output of the amplifier at one terminal, whether the amplifier output-side switch is ON or OFF being controlled with a control voltage; and a low-gain circuit including an attenuator for attenuating an input signal and outputting the attenuated signal, and a first switch connected in series with the attenuator, whether the first switch is ON or OFF being controlled with the control voltage, wherein one terminal of the low-gain circuit is connected to an input of the amplifier and the other terminal of the low-gain circuit is connected to the other terminal of the amplifier output-side switch, wherein during high-gain operation, the first switch is OFF and the amplifier output-side switch is ON according to the control voltage, and wherein during low-gain operation, power supply to the amplifier is stopped, and the first switch is ON and the amplifier output-side switch is OFF according to the control voltage.

According to the above construction, during low-gain operation, since power supply to the amplifier is stopped, a current hardly flows to the amplifier, and therefore the current consumption can be reduced to near zero. In addition to stopping power supply to the amplifier, the amplifier output-side switch is made OFF. Therefore, at the output of the variable gain amplifier, the impedance of the series circuit including the attenuator and the first switch appears predominant. During high-gain operation, since the output of the amplifier is prevented from feedback, high gain is obtainable and therefore the impedance of the amplifier appears predominant.

By setting the output impedances of the amplifier and the low gain circuit to be equal to the characteristic impedance of a transmission line (normally, 50Ω) deterioration in output return loss is prevented. In this way, according to the present invention, it is possible to attain a variable gain amplifier prevented from deteriorating in output return loss during both high-gain operation and low-gain operation.

In the variable gain amplifier of the present invention, the attenuator preferably comprises a resistor.

In the variable gain amplifier of the present invention, the first switch preferably includes a field effect transistor, whether or not there is conduction between a source and a drain of the transistor being controlled with the control voltage.

In the variable gain amplifier of the present invention, the amplifier output-side switch preferably includes a field effect transistor, whether or not there is conduction between a source and a drain of the transistor being controlled with the control voltage.

In the variable gain amplifier of the present invention, the first switch and the amplifier output-side switch are preferably controlled with a supply voltage applied to the amplifier.

Preferably, the low-gain circuit further includes a second switch that is ON when the first switch is ON and OFF when the first switch is OFF, wherein the first switch, the attenuator, and the second switch are connected in series in this order.

The second switch preferably includes a field effect transistor, whether or not there is conduction between a source and a drain of the transistor being controlled with the control voltage.

Alternatively, the variable gain amplifier of the present invention includes: an amplifier for amplifying an input signal and outputting the amplified signal; an output matching circuit connected to an output of the amplifier at one terminal; and a low-gain circuit including an attenuator for attenuating an input signal and outputting the attenuated signal, and a first switch connected in series with the attenuator, whether the first switch is ON or OFF being controlled with a control voltage, wherein one terminal of the low-gain circuit is connected to an input of the amplifier and the other terminal of the low-gain circuit is connected to the other terminal of the output matching circuit, wherein during high-gain operation, the first switch is OFF according to the control voltage, and wherein during low-gain operation, power supply to the amplifier is stopped, and the first switch is ON according to the control voltage.

### BRIEF DESCRIPTION OF THE DRAWINGS

FIG. 1 is a circuit diagram of a variable gain amplifier of Embodiment 1 of the present invention.

FIG. 2 is a circuit diagram showing a specific circuit example of the variable gain amplifier shown in FIG. 1.

FIG. 3 is a circuit diagram of a variable gain amplifier of Embodiment 2 of the present invention.

FIG. 4 is a circuit diagram showing a specific circuit example of the variable gain amplifier shown in FIG. 3.

FIG. 5 is a circuit diagram of a variable gain amplifier of Embodiment 3 of the present invention.

FIG. 6 is a circuit diagram of a conventional variable gain amplifier.

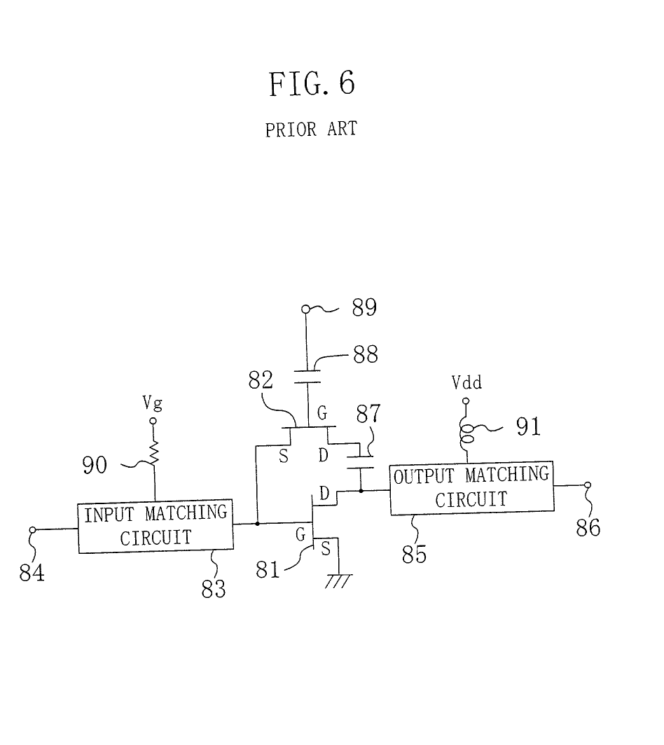

### DESCRIPTION OF THE PREFERRED EMBODIMENTS

Hereinafter, preferred embodiments of the present invention will be described with reference to the accompanying drawings.

### Embodiment 1

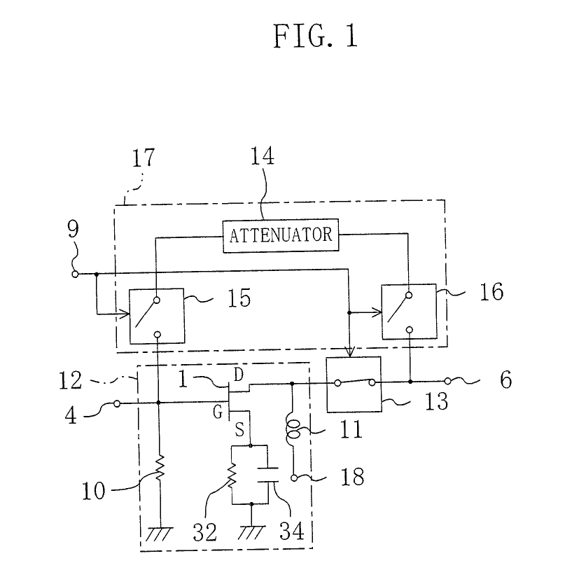

FIG. 1 is a circuit diagram of a variable gain amplifier of Embodiment 1 of the present invention. The variable gain amplifier of FIG. 1 includes a high-frequency amplifier 12, an amplifier output-side switch 13, and a low-gain circuit 17.

Referring to FIG. 1, the high-frequency amplifier 12 includes a FET 1, resistors 10 and 32, a choke coil 11, and a capacitor 34. The gate of the FET 1 is connected with one terminal of the resistor 10, the other terminal of which is grounded. The drain of the FET 1 is connected with one terminal of the choke coil 11, the other terminal of which constitutes an amplifier voltage terminal 18. The source of the FET 1 is grounded via a bias circuit composed of the resistor 32 and the capacitor 34 connected in parallel.

The gate of the FET 1 constitutes an input terminal 4 of the high-frequency amplifier 12, which is also a signal input terminal of the variable gain amplifier of FIG. 1. The drain of the FET 1 is connected with one terminal of the amplifier output-side switch 13, the other terminal of which constitutes an output terminal 6 of the variable gain amplifier of FIG. 1. In other words, the FET 1 and the amplifier output-side switch 13 are connected in series between the input terminal 4 and the output terminal 6.

The low-gain circuit 17 includes an attenuator 14, a first switch 15, and a second switch 16. The attenuator 14 is connected to the gate of the FET 1 via the switch 15 at one terminal, and to the drain of the FET 1 via the switch 16 at the other terminal. In other words, the low-gain circuit 17 includes the switch 15, the attenuator 14, and the switch 16 connected in series in this order. One terminal of this series circuit is connected to an input of the high-frequency amplifier 12, while the other terminal is connected to the terminal constituting the output terminal 6 of the amplifier output-side switch 13.

A control voltage input via a control terminal 9 is applied to the switches 13, 15, and 16. The switches 13, 15, and 16 are single pole single throw (SPST) type circuits in which the open/close state is controlled with the applied control voltage. The drain voltage at the FET 1 is controlled with a voltage applied to the amplifier voltage terminal 18.

The operation of the variable gain amplifier of FIG. 1 will be described. The variable gain amplifier of FIG. 1 performs high-gain operation when an input signal is weak. During the high-gain operation, the high-frequency amplifier 12 is ON while the low-gain circuit 17 is OFF. Specifically, to turn ON the high-frequency amplifier 12, a voltage permitting the FET 1 to operate is supplied to the amplifier voltage terminal 18. To turn OFF the low-gain circuit 17, a voltage that makes the switches 15 and 16 “open” (out of conduction), is applied to the control terminal 9. Simultaneously, this voltage makes the switch 13 “closed” (in conduction).

Because the switches 15 and 16 are open, the impedance of the low-gain circuit 17 is the infinite. Therefore, the impedance of the high-frequency amplifier 12 is predominant as the output impedance of the variable gain amplifier of FIG. 1.

On the other hand, the variable gain amplifier of FIG. 1 performs low-gain operation when an input signal is strong. During the low-gain operation, the high-frequency amplifier 12 is OFF while the low-gain circuit 17 is ON. To turn ON the low-gain circuit 17, a voltage that makes the switches 15 and 16 “closed” is applied to the control terminal 9. Simultaneously, this voltage makes the switch 13 “open”. To turn OFF the high-frequency amplifier 12, the voltage at the amplifier voltage terminal 18 is set at 0 V, to stop power supply to the high-frequency amplifier 12. Thus, a current hardly flows to the high-frequency amplifier 12.

Because the switch 13 is open, the output impedance of the series circuit essentially composed of the high-frequency amplifier 12 and the switch 13 is the infinite. Therefore, the impedance of the low-gain circuit 17, which is connected in parallel with the high-frequency amplifier 12, appears predominant as the output impedance of the variable gain amplifier of FIG. 1. In general, the impedance of the low-gain circuit 17 is designed to 50Ω, which is equal to the characteristic impedance of a transmission line. Thus, the output return loss is prevented from deteriorating.

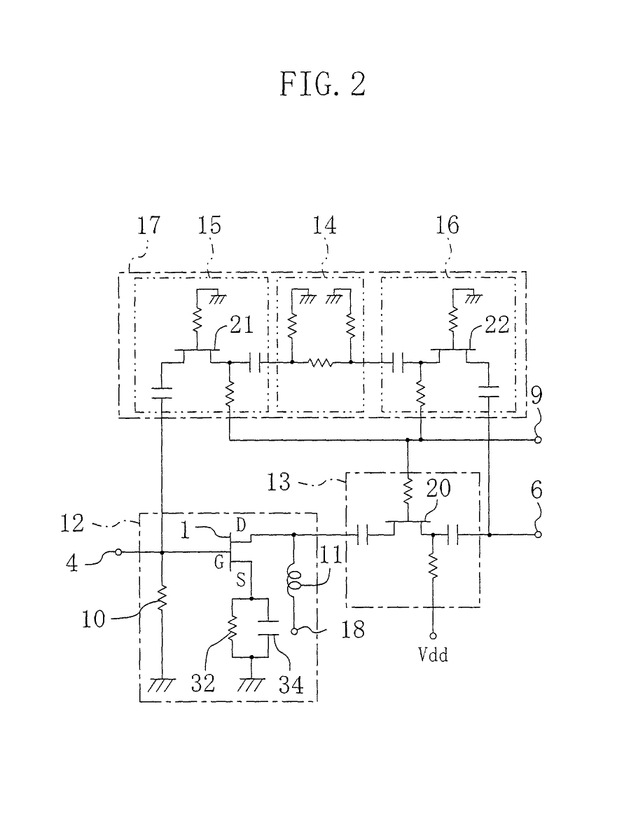

FIG. 2 is a circuit diagram showing a specific circuit example of the variable gain amplifier of FIG. 1. The attenuator 14 is constructed of a π-type resistance attenuator often used in general. The switches 13, 15, and 16 are constructed of SPST type switches including FETs 20, 21, 22, respectively.

The circuit of the switch 13 is constructed so that the switch is closed when the control voltage applied to the control terminal 9 is high and is open when it is low. Contrarily, the circuits of the switches 15 and 16 are constructed so that the switch is open when the control voltage is high and is closed when it is low.

The loss of the low-gain circuit 17 is determined by the attenuation level of the attenuator 14 and the insertion loss of the switches 15 and 16. The insertion loss of the switches 15 and 16 depends on the frequency of a signal and the gate length and gate width of the FET. As the gate length is 0.2 μm and the gate width is 400 μm, the loss is about 0.8 dB at a frequency of 2 GHz.

Measurement results of the variable gain amplifier of FIG. 2 when operated at a frequency of 2 GHz and a supply voltage of 3 V are as follows, for example. During high-gain operation, the current of 3 mA, the gain of 15 dB, the input return loss of −10 dB, and the output return loss of −10 dB were obtained with the control voltage of 3 V. During low-gain operation, the current of 0 mA, the gain of −15 dB, the input return loss of −10 dB, and the output return loss of 12 dB were obtained with the control voltage of 0 V.

Note that the gain of the variable gain amplifier during low-gain operation can be adjusted by setting the resistance value in the attenuator 14 so as to obtain a desired attenuation level.

### Embodiment 2

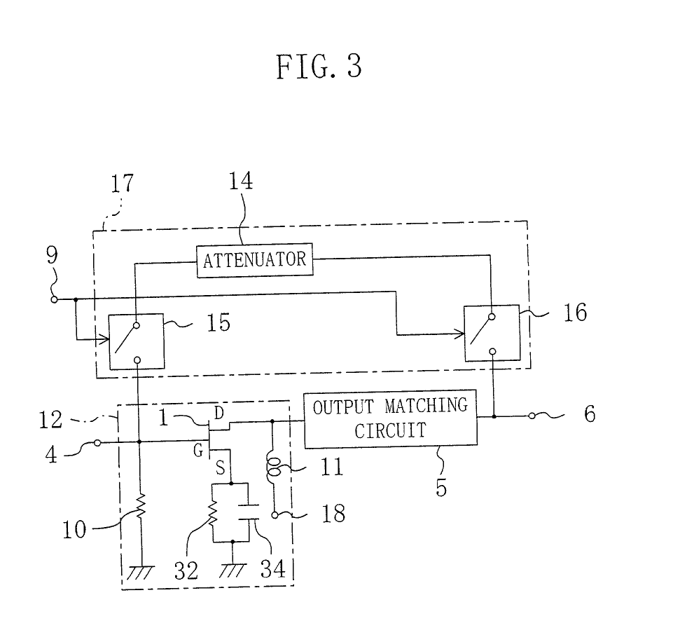

FIG. 3 is a circuit diagram of a variable gain amplifier of Embodiment 2 of the present invention. The variable gain amplifier of FIG. 3 is obtained by replacing the switch 13 of the variable gain amplifier of FIG. 1 with an output matching circuit 5 for matching the output impedance of FET 1.

The operation of the variable gain amplifier of FIG. 3 will be described. The operation of the switches 15 and 16 is the same as those of the variable gain amplifier of FIG. 1.

The output matching circuit 5 is designed to have an impedance at which the gain of the high-frequency amplifier 12 is maximum (normally, 50Ω) during high-gain operation (when a small signal is input), and have an output impedance near the infinite during low-gain operation (when a large signal is input). Therefore, since the output impedance of the variable gain amplifier of FIG. 3 changes as the variable gain amplifier of FIG. 1 does, the output return loss is prevented from deteriorating during both the high-gain operation and the low-gain operation.

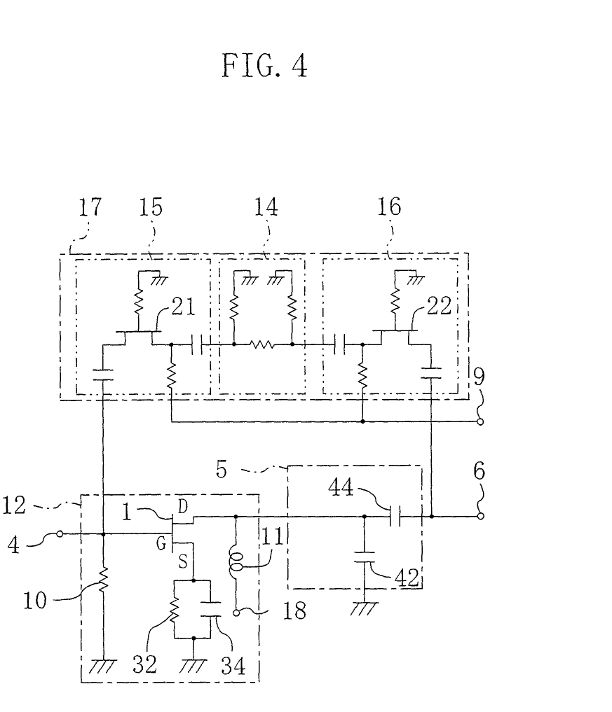

FIG. 4 is a circuit diagram showing a specific circuit example of the variable gain amplifier of FIG. 3. In FIG. 4, the attenuator 14 and the switches 15 and 16 are the same as those described with reference to FIG. 2. The output matching circuit 5 includes a capacitor 42 connected in parallel with the high-frequency amplifier 12 and a capacitor 44 connected in series with the high-frequency amplifier 12. The capacitor 42 is connected to the drain of the FET 1 at one terminal and grounded at the other terminal. The capacitor 44 is connected to the drain of the FET 1 at one terminal, and the other terminal thereof constitutes the output terminal 6.

The values of the capacitors 42 and 44 of the output matching circuit 5 are set so that the output impedance of the high-frequency amplifier 12 is roughly equal to the characteristic impedance of a transmission line (normally, 50Ω) during high-gain operation. For example, the value of the capacitor 42 is 1 pF and the value of the capacitor 44 is 2 pF. Another circuit using an inductor may also be used as the output matching circuit 5.

Measurement results of the variable gain amplifier of FIG. 4 when operated at a frequency of 2 GHz and a supply voltage of 3 V are as follows, for example. During the high-gain operation, the current of 3 mA, the gain of 15 dB, the input return loss of −10 dB, and the output return loss of 10 dB were obtained with the control voltage of 3 V. During the low-gain operation, the current of 0 mA, the gain of −15 dB, the input return loss of −10 dB, and the output return loss of −11 dB were obtained with the control voltage of 0 V.

As in Embodiment 1, the gain of the variable gain amplifier during the low-gain operation can be adjusted by changing the attenuation level of the attenuator 14.

### Embodiment 3

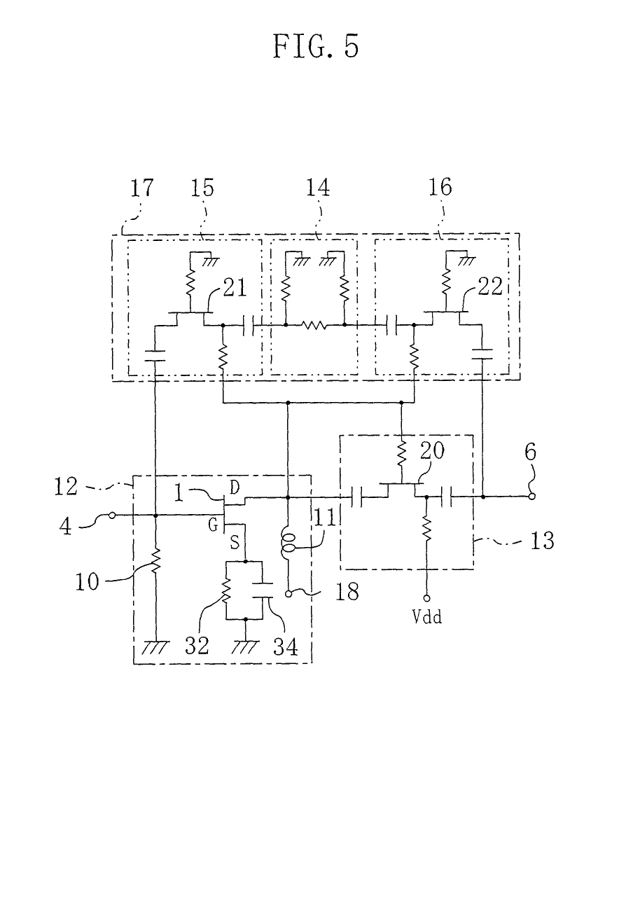

FIG. 5 is a circuit diagram of a variable gain amplifier of Embodiment 3 of the present invention. In the variable gain amplifier shown in FIGS. 1 and 2, the open/close state of the switches 13, 15, and 16 was controlled with the voltage applied through the control terminal 9. In the variable gain amplifier of FIG. 5, the switches 13, 15, and 16 are connected to the drain of the FET 1, and the open/close state is controlled with the voltage applied through the amplifier voltage terminal 18 connected via the choke coil 11. That is, the amplifier voltage terminal 18 shown in FIG. 5 is a terminal combining the amplifier voltage terminal 18 and the control terminal 9 shown in FIG. 2.

In order to avoid an influence that may be caused by combining the control terminal 9 and the amplifier voltage terminal 18 into one terminal, all of bias control resistors of the switches 13, 15, and 16 are needed to be set at a value as high as several tens to several hundreds of kΩ. By this setting, the high-frequency amplifier 12 is prevented from deteriorating in characteristics due to feedback to the FET 1. As for the low-gain circuit 17, the choke coil 11 that may influence the characteristics at a high frequency is connected to the low-gain circuit 17 via the bias control resistors of the switches 15 and 16. These bias control resistors are set to have high impedance so that the choke coil 11 can be ignored. Therefore, the low-gain circuit 17 is prevented from deteriorating in characteristics due to the existence of the choke coil 11.

By combining the control terminal 9 and the amplifier voltage terminal 18 into one terminal, the number of pins can be reduced and thus a package can be downsized in an occasion of integration of the variable gain amplifier.

In the above embodiments, both the switches 15 and 16 were opened to turn OFF the low-gain circuit 17. Alternatively, the low-gain circuit 17 may be turned OFF by opening either one of the switches 15 and 16.

Alternatively, only one of the switches 15 and 16 may be provided.

As described above, according to the present invention, the high-frequency amplifier and the low-gain circuit are connected in parallel with each other. The amplifier output-side switch that blocks a change in impedance depending on the ON/OFF state of the high-frequency amplifier from being output, or the output matching circuit that adjusts the impedance, is provided between the high-frequency amplifier and the output terminal of the variable gain amplifier. Therefore, according to the present invention, it is possible to provide a variable gain amplifier in which the current consumption can be reduced to near zero during low-gain operation and the output return loss does not deteriorate during both high-gain operation and low-gain operation.

While the present invention has been described in a preferred embodiment, it will be apparent to those skilled in the art that the disclosed invention may be modified in numerous ways and may assume many embodiments other than that specifically set out and described above. Accordingly, it is intended by the appended claims to cover all modifications of the invention that fall within the true spirit and scope of the invention.

What is claimed is:

1. A variable gain amplifier comprising:
an amplifier for amplifying an input signal and outputting the amplified signal;
an amplifier output-side switch connected to an output of the amplifier at one terminal, whether the amplifier output-side switch is ON or OFF being controlled with a control voltage; and
a low-gain circuit including an attenuator for attenuating an input signal and outputting the attenuated signal, and a first switch connected in series with the attenuator, whether the first switch is ON or OFF being controlled with the control voltage,
wherein one terminal of the low-gain circuit is connected to an input of the amplifier and the other terminal of the low-gain circuit is connected to the other terminal of the amplifier output-side switch,
wherein during high-gain operation, the first switch is OFF and the amplifier output-side switch is ON according to the control voltage, and
wherein during low-gain operation, power supply to the amplifier is stopped, and the first switch is ON and the amplifier output-side switch is OFF according to the control voltage.

2. The variable gain amplifier of claim 1, wherein the attenuator comprises a resistor.

3. The variable gain amplifier of claim 1, wherein the first switch comprises a field effect transistor, whether or not there is conduction between a source and a drain of the transistor being controlled with the control voltage.

4. The variable gain amplifier of claim 1, wherein the amplifier output-side switch comprises a field effect transistor, whether or not there is conduction between a source and a drain of the transistor being controlled with the control voltage.

5. The variable gain amplifier of claim 1, wherein the first switch and the amplifier output-side switch are controlled with a supply voltage applied to the amplifier.

6. The variable gain amplifier of claim 1, wherein the low-gain circuit further comprises a second switch that is ON when the first switch is ON and OFF when the first switch is OFF, and
wherein the first switch, the attenuator, and the second switch are connected in series in this order.

7. The variable gain amplifier of claim 6, wherein the second switch comprises a field effect transistor, whether or not there is conduction between a source and a drain of the transistor being controlled with the control voltage.

8. A variable gain amplifier comprising:
an amplifier for amplifying an input signal and outputting the amplified signal;
an output matching circuit connected to an output of the amplifier at one terminal; and
a low-gain circuit including an attenuator for attenuating an input signal and outputting the attenuated signal, and a first switch connected in series with the attenuator, whether the first switch is ON or OFF being controlled with a control voltage,
wherein one terminal of the low-gain circuit is connected to an input of the amplifier and the other terminal of the low-gain circuit is connected to the other terminal of the output matching circuit,
wherein during high-gain operation, the first switch is OFF according to the control voltage, and
wherein during low-gain operation, power supply to the amplifier is stopped, and the first switch is ON according to the control voltage.

9. The variable gain amplifier of claim 8, wherein the attenuator comprises a resistor.

10. The variable gain amplifier of claim 8, wherein the first switch comprises a field effect transistor, whether or not there is conduction between a source and a drain of the transistor being controlled with the control voltage.

11. The variable gain amplifier of claim 8, wherein the first switch is controlled with a supply voltage applied to the amplifier.

12. The variable gain amplifier of claim 8, wherein the low-gain circuit further comprises a second switch that is ON when the first switch is ON and OFF when the first switch is OFF,
wherein the first switch, the attenuator, and the second switch are connected in series in this order.

13. The variable gain amplifier of claim 12, wherein the second switch comprises a field effect transistor, whether or not there is conduction between a source and a drain of the transistor being controlled with the control voltage.
